(19) United States
(12) Patent Application Publication
(10) Pub. No.: US 2020/0176028 A1
(43) Pub. Date: Jun. 4, 2020

(54) Atomic Scale Data Storage Device by Means of Atomic Vacancy Manipulation

(71) Applicant: Technische Universiteit Delft, Delft (NL)

(72) Inventors: Ranko Toskovic, Delft (NL); Eleonora Fahrenfort, Delft (NL); Marnix Rebergen, Delft (NL); Alexander Ferdinand Otte, Delft (NL); Floris Eduard Kalff, Delft (NL); Jan Girovsky, Delft (NL)

(21) Appl. No.: 16/080,990

(22) PCT Filed: Feb. 27, 2017
(86) PCT No.: PCT/NL2017/050118

§ 371 Date: Aug. 29, 2018

(30) Foreign Application Priority Data
Feb. 29, 2016 (NL) 2016335

(51) Int. Cl. G11B 11/00; G11B 9/06; G11B 9/14; H01L 21/02; B82Y 10/00

(52) U.S. Cl. CPC G11B 11/007; G11B 9/063; B82Y 10/00; H01L 21/02436; G11B 9/14

(57) ABSTRACT

The present invention is in the field of an atomic scale data storage device which uses vacancy manipulation, a method of providing said device, and a method of operating said device. Prior art mass data storage devices typically rely on magnetic materials forming discrete arrays or on nanoscale transistors. Further examples are e.g. optical systems such as a DVD and a compact disk. These devices and systems have a large, but for some applications still limited, storage capacity.

### FIELD OF THE INVENTION

The present invention is in the field of an atomic scale data storage device which uses manipulation of atomic vacancies, a method of providing said device, and a method of operating said device.

### BACKGROUND OF THE INVENTION

The present invention is in the field of storing data, devices therefore, a method of constructing said device, and a method of operating said device.

Prior art mass data storage devices typically rely on magnetic materials forming discrete arrays or on nanoscale transistors. Further examples are e.g. optical systems such as a DVD and a compact disk. The precise form and technology of these devices may vary. Clearly the amount of data stored has increased rapidly over the years, typically following Moore's law in view of data density. A maximum storage capacity can now be in the order of terabytes and a maximum read/write speed in the order of Gbit/s. A maximum storage density is in the order of about 0.2 Tbit/cm², or 2*10⁻³ bit/nm². Typical dimensions of a bit are therefore at the best about 25*20 (=500) nm² per individual bit.

It is noted that the ongoing miniaturization of data storage is coming to a halt, as existing data storage production techniques, typically semiconductor production techniques, such as lithography, and forming of transistors, can no longer be scaled down into a regime where functional components would consist out of several (1-10) atoms.

Alternative solutions include encoding of data in a magnetic state or charge state of individual atoms or assemblies of atoms. None of these have ever resulted in memories larger than 1 byte.

It is noted that for some applications huge amounts of data storage means are required. Quite often this data need only be stored, typically for a prolonged period of time, e.g. years.

Some scientific papers relate to moving atoms on a surface.

R. Bennewitz et al., Nanotechnology. 13, pp. 499-502 (2002) show controlled removal of individual Si atoms on a Si(111) metal surface. Removed metal atoms can however not be repositioned back onto the Si surface without formatting the substrate (i.e. regenerating the entire surface). Therefore no rewritable data storage is possible effectively.

Z. Li et al., ACS Nano. 9, pp. 5318-5325 (2015): show manipulation of vacancies on NaCl. They however do not demonstrate directional control in moving the vacancies, and no stability beyond helium temperature (4.5 K). In addition the areas of manipulation are very small (a few nm² at the most), i.e. limited in size.

S. Loth et al., Science. 335, pp. 196-199 (2012) show manipulation of a 1 byte rewritable structure in magnetic states of eight 12-atom structures (96 atoms total) of Fe atoms on a Cu₂N/Cu(100) surface. The structures are stable only at or below 1.5 K and can most likely not be applied for large-scale data storage.

Incidentally JP 2 930 103 B2 recites an arbitrary semiconductor surface having a few atoms of both Cl and Al adsorbed thereon. The surface is claimed to provide a pattern with adsorbed atoms of different electroconductivity.

Also U.S. Pat. No. 4,987,312 B recites a substrate surface, such as Pt(111), with Xe atoms positioned thereon. In a further example atoms are positioned on an arbitrary surface in between rows.

None of the two above patent documents show large scale data storage, nor stable data storage. They only relate to moving an atom over a surface and at the best forming a small nanoscopic pattern.

The present invention relates to an improved data storage device, a method of providing such a device, and a method of operating said device, which overcome one or more of the above disadvantages, without jeopardizing functionality and advantages.

### SUMMARY OF THE INVENTION

The present invention relates in a first aspect to a device according to claim 1. By employing bottom-up assembly rather than top-down miniaturization, the present invention provides the possibility to create data storage solutions on a true atomic scale. The present device provides positioning of atomic vacancies in a grid of atoms, allowing for storage of large quantities of data. An example already shows an aerial data density of 1 bit/nm² (i.e. 500 Terabits per square inch (Tbpsi)), outperforming current state-of-the-art commercial data storage devices by a factor 500. Such is especially useful for large storage of data, such as in a data centre.

In the present device data is stored on a true atomic scale. Crystallographic lattice positions are used to store data. Thereto a metallic single crystal surface is provided. The surface is single crystalline over at least part of a total crystal surface, and preferably fully single crystalline. It is noted that in view of thermodynamics a surface may comprise impurities and/or defects, albeit typically in a low density (<1 defect/nm²). The surface needs to be stable at operating conditions. A measure of stability is for instance the so-called roughening transition temperature. The roughening transition temperature can be calculated using Burton-Cabrera-Frank models and subsequent models and can typically be determined experimentally relatively easily. The present metallic crystal surface preferably has a roughness transition temperature above operating conditions+100 K, preferably above+250 K, such as above+600 K, i.e. higher or much higher than operating conditions. On the single crystal surface a two-dimensional lattice is present, comprising positions in the lattice, which positions consist of non-metallic atoms representing a filled state or unfilled positions representing vacancies. The two-dimensional lattice may be considered as to be present due to the metallic single crystal surface, the surface representing a two-dimensional cut in an infinite crystal and therefore having in the surface positons being available for occupation (in this case by the metal atoms) in a two-dimensional lattice (see e.g. FIG. 1). These position can be filled (or occupied) and unfilled (or empty). For good performance the present device comprises a temperature regulator for maintaining a temperature, such as a fan as is typically used in a computer. In order to move the non-metallic atoms, thereby leaving behind unfilled positions (vacancies) and occupying unfilled positions, a positioning device arranged to move non-metallic atoms over the dimensional lattice is provided (for putting an atom in a specified position on the two-dimensional lattice). The positioning device moves individual atoms over the surface. The positioning device may also relate to a multitude of positioning devices, operating in dependence or independently of one and another, e.g. operating in parallel and/or in series, such as 2-10 positioning devices per metal surface. The at least one positioning device is typically controlled by a controller, such as a processor, and typically by software; such controlling is on a bit level comparable to prior art storage devices. In order to maintain the non-metallic atoms in position, and to prevent external (e.g. environmental) influence from degrading and/or changing the device the surface and two-dimensional lattice are kept at a pressure from atmospheric to high vacuum. The pressure may be varied and adapted based on the characteristics of the device. In a preferred embodiment an inert gas is provided, such as nitrogen, a noble gas, such as He, Ar, and Ne, and the like. The pressure is from 10⁻¹²-100 kPa, preferably from 10¹⁰-50 kPa, more preferably from 10⁻⁹-20 kPa, even more preferably from 10⁻⁸-10 kPa, such as from 10⁻⁶-5 kPa.

The term “metallic” is used to indicate metallic properties, such as an electrical conductivity of >10³ S/m (@ 20° C.), preferably >10⁵ S/m, typically 10⁶ S/m. Semiconducting materials, such as Si, Ge, and GaAs do not fall under the scope of metallic.

The term “non-metallic” is used to indicate non-metallic properties. Chemically non-metallic atoms may form a negatively charged ion and are hence capable of forming a salt. Clearly noble gases are not non-metallic atoms (and likewise not metallic atoms either).

The present metallic and non-metal atom are capable of forming a salt. Such is advantageous in terms of production of the present device. By depositing a salt, such as for example CuCl₂, on a substrate, such as Cu, the non-metallic atoms become directly available for data storage. The salt, or likewise the metal and non-metal, may also be deposited using a precursor.

Inventors have found a way to store digital data on the atomic scale. This is made possible through the fact that individual atomic vacancies (i.e. missing atoms) in a two-dimensional lattice of e.g. halogen atoms atop a metallic single crystal can be manipulated into an arrangement of choice. In addition the arrangement is relatively robust against thermal fluctuations. As a prototype, inventors created a 1 kB (8000 bits) memory, assembled from individual Cl atoms and vacancies on a Cu(100) crystal surface by means of low-temperature scanning tunnelling microscopy (STM). The areal density of this memory is 1 bit/nm² (500 Tbpsi), compared to 2*10⁻³ bit/nm² (1 Tbpsi) for current state-of-the-art hard disk drives. The vacancies and likewise non-metal atoms are found to be stable up to a temperature of 77 K. At present, without any specific effort, inventors established to produce a device with a memory of about 1 kB which is directly scalable to at least 1 MB. Using standard equipment reading and writing might be considered a bit slow being still below 1 kb/sec. However, the precise location of the vacancies and non-metal atoms can be manipulated such as by STM with a very high level of control (and without a need to pick atoms with the tip, i.e. vertical atom manipulation).

As inventors showed these properties allow to position thousands of vacancies at predefined atomic sites.

Inventors consider that by making use of available high-frequency STM electronics, readout speeds in the order of 1 Mb/s are attainable. Whereas the present invention relates to a two-dimensional layout, by yielding vertical stacking of 2D crystals a three-dimensional scaling-up of petabyte atomic memories is possible.

Inventors have tested stability of the present device. Thereto a kbyte memory was written with data. A few days later no data was lost (or altered). Calculations indicate that stability times exceed a year.

It is considered a specific strength of the present invention that e.g. the lattice of halogen atoms forms an ideal square template grid for the digital memory. This grid allows for very precise positioning of vacancies in a discrete manner, e.g. in the up position (0) or the down position (1). In addition, the grid provides the possibility to create atomic scale markers that can be used for navigation through the memory. The figures show an STM topographic scan of the 1 kB memory measured at 1.5 K.

It is noted that manipulation through STM of individual atoms atop a flat surface has been demonstrated before. However, these manipulated atoms on the surface are typically found to be stable only at temperatures below 10K and provide a not well defined grid.

Compared to alternatives, the demonstrated memory is superior in terms of storage capacity, reliability, digital discreteness and thermal stability. The read and write speed are however not optimal yet. Also, some scaling issues might still need to be addressed.

Thereby the present invention provides a solution to one or more of the above mentioned problems.

Advantages of the present invention are detailed throughout the description.

### DETAILED DESCRIPTION OF THE INVENTION

The present invention relates in a first aspect to a device according to claim 1.

In an exemplary embodiment of the present device the metal is selected from elements of group 3-12, rows 4-6, such as Ti, V, Cr, Mn, Co, Ni, Cu, Zr, Mo, Pd, Ag, W, Pt and Au, and combinations thereof, and the non-metallic atoms are selected from elements of groups 13-17, rows 2-6, such as F, P, S, Cl, Se, Br and I, and combinations thereof. So in principle a wide variety of combination may be possible. In view of performance, e.g. in terms of stability over time and in view of operating temperature, some combinations are preferred. For instance halogen atoms as non-metal in combination with highly symmetrical crystal surface are preferred.

In an exemplary embodiment of the present device the two-dimensional lattice comprises >50% filled positions, preferably >75%, even more preferably >85%. As such unfilled positions can be separated from one and another, preferably such that no unfilled position is adjacent, vertically, horizontally or diagonally, to a further unfilled position (see e.g. FIGS. 3 and 4). It has been found that especially writing of data can be performed in a more reliable manner.

In an exemplary embodiment of the present device the crystallographic lattice of the metal has at least one perpendicular symmetry element selected from a two-fold axis, a mirror, a four-fold axis, a three-fold axis, an inverse four-fold axis, a six-fold axis, and an inverse three-fold axis. In view of stability, especially at relatively higher temperatures, and in view of data storage these regular lattices are found to perform best.

In an exemplary embodiment of the present device the metallic single crystal has a crystal structure selected from Bravais families c, h, t or o, such as orthorhombic, primitive orthorhombic, hexagonal, tetragonal, primitive tetragonal, primitive cubic, cubic, such as bcc, fcc, hcp, and zinc blende. In view of stability, especially at relatively higher temperatures, and in view of data storage these regular lattices are found to perform best.

In an exemplary embodiment of the present device the metal is selected from Cu, V, Cr, Ni, Au, Ag, Pd, and Pt.

In an exemplary embodiment of the present device the non-metallic atoms are selected from halogens, such as CI, Br and I. It has been found that especially these non-metal atoms perform well in terms of characteristics of the present invention.

In an exemplary embodiment of the present device the metallic single crystal surface is provided on a substrate, optionally with at least one intermediate layer.

As suitable substrates inorganic materials, such as Si, and glass, and suitable organic materials, such as polymers, may be used. Intermediate layers may be formed of materials, typically inorganic materials, preferably an alloy comprising the present metal and the material of the substrate. The intermediate layer may have a composition gradient, wherein a top layer resembles the present metal layer, and a bottom layer resembles the substrate.

In an exemplary embodiment of the present device the crystal surface is a {100}, {110}, or {111} surface.

In an exemplary embodiment of the present device the metal is at least one of Cu, V, Cr, Ni, Au, Ag, Pd, and Pt, and the non-metallic atoms are at least one of Cl, Br and I, and the metallic single crystal has a crystallographic lattice with at least one perpendicular symmetry element selected from a two-fold axis, a mirror, a four-fold axis, a three-fold axis, an in-verse four-fold axis, a six-fold axis, and an inverse three-fold axis, and the crystal surface is at least one of a {100}, {110}, and {111} surface. Examples hereof are non-metal terminated surfaces such as Cl and I on Cu(100), Br and Cl on V (001), I and Br on Cr(100), Cl and I on Ni(100), Br and Cl on Au(001), I and Br on Pd(010), and Cl and Br on Pt(100).

In an exemplary embodiment the present device comprises a cooler for maintaining a temperature below 273 K, preferably below 250 K, more preferably below 200 K, such as below 77 K. It is noted that the present operation temperature is close to the maintained temperature, i.e. relatively far above 0 K, typically >70 K there above, preferably >100 K there above, more preferably >200 K there above. It is considered surprising that the present metal lattice comprising non-metal atoms is stable at relatively higher temperatures. By adapting boundary conditions, such as metal, non-metal, and so on, even higher operation temperatures compared to the present examples can be achieved with the present device.

In an exemplary embodiment of the present device the two-dimensional lattice of halogen atoms comprises position markers for the positioning device. Examples of such markers are given in FIG. 4. In the present invention the position markers make use of 9 available positions; an “X” indicates a blocked section, whereas a “\” indicates a section comprising data or available for storing data. Likewise a “>” and a “V” indicate the start and the end of a line, respectively. It is noted that these markers have a more optical appearance (X, >, V and \). In principle any suitable “symbol” can be used as position marker. The position marker may also represent a binary code, each position of the marker representing a (0) or (1); with nine positions a 9-bit code is available.

In an exemplary embodiment of the present device the positioning device uses atomic force or electron tunnelling current for positioning, such as an AFM-type device or STM-type device.

In an exemplary embodiment of the present device a 1/n fraction of the metallic lattice is used and a remainder of the metallic lattice is discarded for data storage, wherein n is 2, 3 or 4. If for instance so-called (√2×√2)R45 cell domains are used (following Wood's notation), only of the crystallographic positions ay be used. Such may for instance also be the case where a fraction of the metallic lattice is covered due to a surface reconstruction of the non-metallic atoms on the metallic crystal surface.

In an exemplary embodiment of the present device the metallic single crystal surface has a defect density of less than 1/10⁴ nm², preferably less than 5/10⁵ nm², more preferably less than 1/10⁵ nm², even more preferably less than 5/10⁶ nm², such as less than 2/10⁶ nm². The defect density is preferably as low as possible, e.g. in view of reliability and in view of available space for data storage. Upon further improving the present method very low defect densities are obtainable, e.g. comparable to Si-based devices.

In an exemplary embodiment of the present device the metallic crystal surface is divided into regular sections, wherein section are separated from one and another. Each individual section can be used for storing and writing data. In principle any size may be considered. From a practical point of view sizes are typically not too large and not too small, e.g. comprising 2⁶-2²⁰ bits, such as 2⁸-2¹⁰ bits. Section are typically separated from one and another, such as by a free zone.

In an exemplary embodiment the present device comprises on the metallic lattice at least one interchangeable combination of a non-metallic atom and an on the lattice adjacent vacancy (NM-AV or AV-NM). These combination may represent a binary status, e.g. (1) and (0), or vice versa.

In an exemplary embodiment the present device comprises on the metallic lattice at least one region for storing non-metallic atoms for filling a vacancy on the lattice. As such a versatility of the present device is improved.

In a second aspect the present invention relates to a method of providing the present device, comprising the steps of, providing a crystalline metallic surface, optionally cleaning the crystalline metallic surface, and depositing non-metallic atoms on the surface.

In an exemplary embodiment of the present method the non-metallic atoms are deposited as a salt of the metal of the metallic surface and the non-metallic atoms.

In an exemplary embodiment of the present method depositing is by thermal evaporation, sputtering, LPCVD, CVD, ALD, PLD, or PVD, preferably thermal evaporation.

In a third aspect the present invention relates to a method of operating the present device, comprising the steps of providing the device, writing data on the device by moving at least one non-metallic atom over the lattice from a first position to a second position. A success rate of moving atoms around in a desired direction and towards a desired position is at present above 99%, or likewise a chance P of success is >0.99. In any case, in view of the nature of the process of moving atoms around according to the invention from a physical point of view there is always a limited chance of success involved. Control software can be used and is used to correct for such imperfections.

In an exemplary embodiment the present method comprises the step of reading data.

In an exemplary embodiment the present method comprises the step of marking sectors, such as bad sectors, available sectors, readable sectors, writable sectors, and combinations thereof.

The invention is further detailed by the accompanying figures and examples, which are exemplary and explanatory of nature and are not limiting the scope of the invention. To the person skilled in the art it may be clear that many variants, being obvious or not, may be conceivable falling within the scope of protection, defined by the present claims.

### SUMMARY OF FIGURES

FIG. 1 shows a crystal lattice and positions thereon.

FIG. 2 shows movement of a non-metal atom.

FIG. 3a-c shows a bit convention.

FIG. 4 shows a partition of an atomic scale memory.

### DETAILED DESCRIPTION OF FIGURES

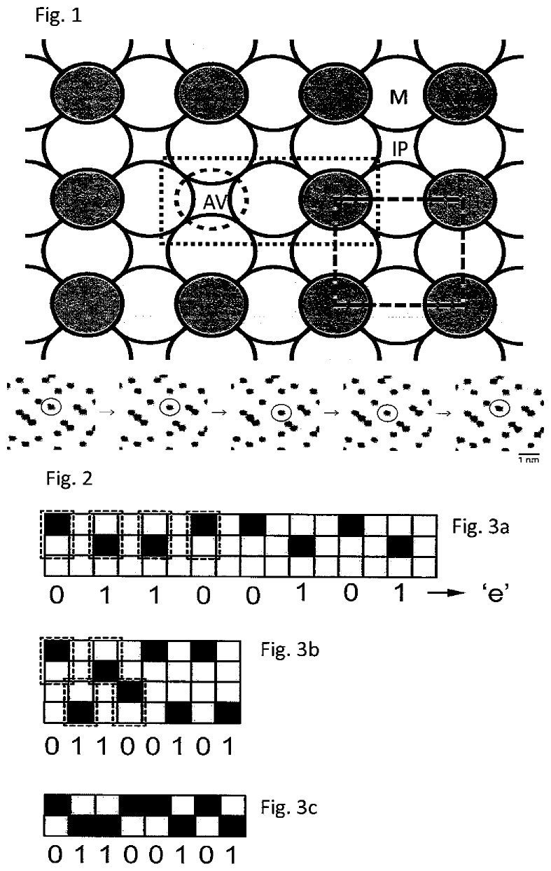

FIG. 1 shows a crystal lattice and positions thereon. A crystallographic surface of metal atoms (M) is shown, in this case relating to a (100) surface. On the single crystal surface a two-dimensional lattice comprising positions in the lattice with non-metallic atoms (NM) representing a filled state and unfilled positions representing vacancies (AV) are visible. The two-dimensional lattice in this example relates to a so-called (√2×√2)R45 sub-lattice, as intermediate positions (IP) are not used for data storage; in other words only half of the available positions is used. The (√2×√2)R45 sub-lattice is indicated by a dashed line. The status of each position on the lattice may reflect a binary status wherein the non-metal may represent a (1) and the vacancy a (0), or vice versa. In an alternative approach, e.g. in view of shifting of the non-metal atom, a combination of two adjacent positions, indicated by a dotted line, may represent a binary status; the combination AV-NM may represent a (1), whereas the combination NM-AV may represent a (0), or vice versa; a consequence thereof is that the data density is half of the maximum density.

FIG. 2 shows an STM-image of movement of a non-metal atom. The non-metal atom, in casu a Cl-atom, is indicated with a circle. In four sequential steps it is moved one position to the right, one position downwards, one position to the left, and finally one position upwards, back to its original position. In the lower right a scale bar representing 1 nm is shown.

FIG. 3a shows an exemplary bit convention. Therein a first column is used, a second comprises non-metal atoms and contains no information, a third is used again, and so on. The top two rows are used for storing data, followed by a row comprising only non-metal atoms, which latter row can be regarded as a spatial division between two subsequent double rows for storing information; in other words, in a vertical direction the three rows shown can be repeated. The first bit indicated by a dashed line represent an AV-NM configuration, which configuration can be attributed with a binary “0”. The next bit is a “1”, and so on. An 8-bit configuration representing “01100101” is shown. In the figure some 5/6 (83.3% of the positions are filled (greyish area).

In FIGS. 3b and 3c a similar layout is shown as in FIG. 3a. Therein 75% and 50% of the positions are filled, respectively.

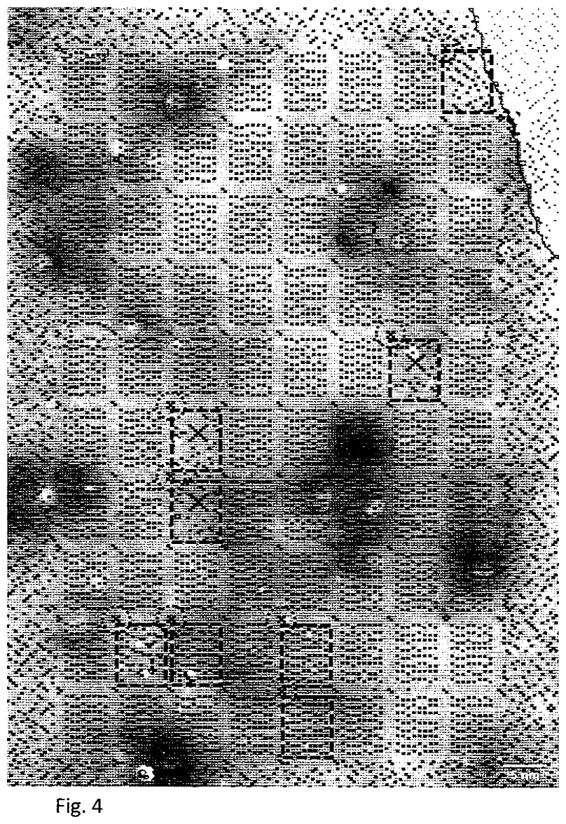

FIG. 4 shows a partition of an atomic scale memory. The black spots represent non-metal atoms, in casu Cl, on a metal surface, in casu Cu(100), whereas the regular white spots represent vacancies. A partition of the lattice into 8 by 10 sections is shown. Eight sections, indicated with dashed lines, are discarded for data storage. To mark such discarded sections, or likewise for other purposes, position markers are provided on the lattice, indicated with a circular dotted line. Each section comprises 8 horizontal positions, separated by a non-used position, and 8 vertical positions, separated by two positions, of which one position may be used to move the non-metal atom to.

The dashed-dotted section in the top-left corner indicates an 8 bits-array having 01001111 vertical bits (AV-NM etc.). Below each bit a NM Cl-atom is present forming a row of NM-atoms. Then, below the 8-bits array, a further 8 bits array is indicated (01101110), and so on.

Each section is separated by a small area, which is not used for data storage. These small areas may be used for position marking. In the present invention the position markers make use of 9 available positions; an “X” indicates a blocked section, whereas a “\” indicates a section comprising data or available for storing data. A “>” and a “V” indicate the start and the end of a line, respectively. Examples thereof are indicated with dashed lines.

Adjacent to the sections, e.g. on the left, right, top and bottom side of the image, regions are available, e.g. for storing non-metal atoms.

On the top right side of the image a crystallographic imperfection is visible, which relates to a step between a first and second surface, the surfaces being at least one lattice constant apart.

The figures are further detailed in the description.

### EXAMPLES/EXPERIMENTS

The invention although described in detailed explanatory context may be best understood in conjunction with the accompanying examples and figures as detailed above. Details mentioned below relate to an article submitted for publication by Kalff et al., entitled “A Kilobyte Rewritable Atomic Memory”.

### Experiment 1

A chlorinated copper surface is created in ultrahigh vacuum through the evaporation of anhydrous CuCl₂ at 300° C. onto a clean Cu(100) crystal surface. The Cu crystal is pre-heated to 100-150° C. prior the CuCl₂ deposition for about 12 minutes and kept at this temperature during the 210 s deposition and the 10 minutes post-anneal. This is found to result in formation of a square reconstruction of Cl atoms with a lattice constant α of 0.36 nm. The Cl coverage (and thereby the vacancy coverage x) can be tuned by varying the duration of evaporation. For instance, an evaporation time of 240 s provides a vacancy coverage of 16.9%, whereas a time of 210 s gave 11.5% on the sample. Such can be determined by using an STM.

The obtained chlorinated surface is found to be resilient to tunnelling currents of up to 2 μA when imaged at positive sample voltages of ˜200 mV or lower.

### Experiment 2

Inventors moved vacancies by injecting a current of 1.0±0.5 μA at a +500 mV sample voltage at a position close to a center of the vacancy to a center of a neighboring Cl atom at the desired location. The STM feedback was kept switched on throughout the manipulation procedure. It was found that a directional reliability (i.e. how often a vacancy moves in the desired direction once it moves) is in excess of 99%. Controlled vacancy movement is at present limited to the (±1,0) and (0,±1) directions on the two dimensional lattice.

### Experiment 3

In this experiment the present inventors used only a part of the two dimensional lattice. In the lattice a vertical pair of a chlorine atom (Cl, or NM) and an adjacent vacancy (AV) were defined as a bit, wherein the AV-Cl configuration represents the “0” and Cl-AV the “1”. In order to avoid vacancies directly neighbouring each other, which could render automated locking of the STM tip on individual vacancies impossible, inventors implemented a row of Cl (NM) atoms to separate bits in both the horizontal and vertical directions. For this reason, 6 lattice sites are needed for a bit, and likewise 48 lattice sites for a byte, resulting in an optimal vacancy coverage 16.7%.

### Experiment 4

Inventors made use of an automated manipulation device that resulted in construction of large numbers of data. A marker at the top left of each block was used to define a scan frame and a lattice for a complete block. After scanning an area, the positions of all vacancies were determined through image recognition. Next, a pathfinding algorithm was used to calculate a positioning sequence, guiding the vacancies to their respective final positions. In addition markers for adjacent blocks were built automatically as part of the construction and leftover vacancies are swept to a side to be used in optional future blocks. Automated construction of a complete block took in the order of 10 minutes.

1-29. (canceled)

30. An atomic scale data storage device of at least one Mb comprising:
a metallic single crystal surface, wherein the surface is stable at operating conditions;
on the single crystal surface a two-dimensional lattice comprising positions in the lattice, which positions consist of non-metallic atoms representing a filled state or unfilled positions representing vacancies, wherein the metallic and non-metal atom are capable of forming a salt;
a temperature regulator for maintaining a temperature; and
a positioning device arranged to move non-metallic atoms over the two-dimensional lattice,
wherein the single crystal surface and two-dimensional lattice are under a pressure of 10⁻¹²-100 kPa.

31. The device according to claim 30, wherein the single crystal surface and two-dimensional lattice are under an inert gas atmosphere.

32. The device according to claim 30, wherein the metal is selected from elements of group 3-12, rows 4-6, and the non-metallic atoms are selected from elements of groups 13-17, rows 2-6.

33. The device according to claim 30, wherein the two-dimensional lattice comprises >50% filled positions.

34. The device according to claim 30, wherein the crystallographic lattice of the metal has at least one perpendicular symmetry element selected from a two-fold axis, a mirror, a four-fold axis, a three-fold axis, an inverse four-fold axis, a six-fold axis, and an inverse three-fold axis.

35. The device according to claim 30, wherein the metal is selected from Cu, V, Cr, Ni, Au, Ag, Pd, and Pt.

36. The device according to claim 30, wherein the non-metallic atoms are selected from halogens.

37. The device according to claim 30, wherein the metallic single crystal surface is provided on a substrate.

38. The device according to claim 37, wherein the metallic single crystal surface is provided on a substrate with at least one intermediate layer.

39. The device according to claim 30, wherein the crystal surface is a {100}, {110}, or {111} surface.

40. The device according to claim 30, comprising a cooler.

41. The device according to claim 30, wherein the two-dimensional lattice of halogen atoms comprises position markers for the positioning device.

42. The device according to claim 30, wherein the positioning device uses atomic force or electron tunnelling current for positioning, such as an AFM-type device or STM-type device.

43. The device according to claim 30, wherein the metallic single crystal surface has a defect density of less than 1/10⁴ nm².

44. The device according to claim 30, comprising on the metallic lattice at least one interchangeable combination of a non-metallic atom and an on the lattice adjacent vacancy.

45. The device according to claim 30, comprising on the metallic lattice at least one region for storing non-metallic atoms for filling a vacancy on the lattice.

46. A method of providing a device according to claim 30, comprising the steps of:
providing a crystalline metallic surface;
optionally cleaning the crystalline metallic surface; and
depositing non-metallic atoms on the surface.

47. A method of operating a device according to claim 30, comprising the steps of:
providing the device; and
writing data on the device by moving at least one non-metallic atom over the lattice from a first position to a second position.
